(19) United States
(12) Patent Application Publication
(10) Pub. No.: US 2026/0305371 A1
(43) Pub. Date: Oct. 1, 2026

(54) SEMICONDUCTOR PACKAGE WITH ALIGNMENT MARKS

(71) Applicant: SAMSUNG ELECTRONICS CO., LTD., Suwon-si (KR)

(72) Inventors: Jaeyoung CHOI, Suwon-si (KR); Youngchan KO, Suwon-si (KR); Dahee KIM, Suwon-si (KR); Wooseok PARK, Suwon-si (KR); Miso SHIN, Suwon-si (KR); MyungDo CHO, Suwon-si (KR); Younchan CHOI, Suwon-si (KR)

(73) Assignee: SAMSUNG ELECTRONICS CO., LTD., Suwon-si (KR)

(21) Appl. No.: 19/577,954

(22) Filed: Mar. 25, 2026

(30) Foreign Application Priority Data
Mar. 25, 2025 (KR) 10-2025-0038296

(51) Int. Cl. H10W 46/00; H10W 70/60; H10W 90/10; H10W 70/652

(52) U.S. Cl. CPC H10W 46/301; H10W 46/607; H10W 70/618; H10W 90/10; H10W 70/6528

(57) ABSTRACT

A semiconductor package includes: an interposer substrate; and a semiconductor chip on the interposer substrate, in which the interposer substrate includes: a bonding pad on a surface of the interposer substrate and connected to the semiconductor chip; an alignment mark spaced apart from the bonding pad in a first direction parallel to the surface of the interposer substrate; and a first metal block and a second metal block, each overlapping with an entire area of the alignment mark in a second direction perpendicular to the surface of the interposer substrate, in which the alignment mark has a first width in the first direction, in which the first metal block has a second width in the first direction, in which the second metal block has a third width in the first direction, and in which each of the second width and the third width is greater than the first width.

This U.S. non-provisional patent application claims priority under 35 U.S.C.§119 to Korean Patent Application No. 10-2025-0038296 filed on Mar. 25, 2025, in the Korean Intellectual Property Office, the entire contents of which are hereby incorporated by reference.

### BACKGROUND

The present disclosure relates to a semiconductor package.

Package technology has been studied to protect a semiconductor chip, transmit electrical signals with external circuits, and emit heat. Package technology may maximize performance in combination with a semiconductor substrate. The package substrate electrically connects the semiconductor chip and the external board, and may mechanically support the semiconductor chip. The Semiconductor chip seeks to be highly integrated and miniaturized, and thus, the package substrate is required to have high-density wiring, high heat dissipation performance, and stable electrical characteristics. Due to this high integration and miniaturization of wiring, wiring patterns may cause optical distortions, thereby making it difficult for an alignment mark to be accurately recognized.

### SUMMARY

An object of present disclosure is to improve visibility of an alignment mark of an interposer.

Another object of present disclosure is to improve a warpage of a semiconductor package.

The problem to be solved by the present disclosure is not limited to the problem mentioned above, and other problems not mentioned may be clearly understood by those skilled in the art from the following description.

According to an aspect of the disclosure, a semiconductor package includes: an interposer substrate; and a semiconductor chip on the interposer substrate, in which the interposer substrate comprises: a bonding pad on a surface of the interposer substrate and connected to the semiconductor chip; an alignment mark spaced apart from the bonding pad in a first direction parallel to the surface of the interposer substrate; and a first metal block and a second metal block, each overlapping with an entire area of the alignment mark in a second direction perpendicular to the surface of the interposer substrate, in which the alignment mark has a first width in the first direction, in which the first metal block has a second width in the first direction, in which the second metal block has a third width in the first direction, and in which each of the second width and the third width is greater than the first width.

According to an aspect of the disclosure, a semiconductor package includes: an interposer substrate; and a first semiconductor chip on the interposer substrate; and a second semiconductor chip on the interposer substrate, in which the first semiconductor chip and the second semiconductor chip are spaced apart from each other in a first direction parallel to a surface of the interposer substrate, and in which the interposer substrate includes: an alignment mark on the surface of the interposer substrate; and a first metal block overlapping the alignment mark in a second direction perpendicular to the surface of the interposer substrate, in which the alignment mark has a first area, in which the first metal block has a second area, in which the second area is greater than the first area, and in which the alignment mark is located within the first metal block.

According to an aspect of the disclosure, a semiconductor package includes: a package substrate; an interposer substrate on the package substrate; a first semiconductor chip on the interposer substrate; and a chip stack structure spaced apart from the first semiconductor chip in a first direction parallel to a surface of the interposer substrate, in which the chip stack structure includes: a second semiconductor chip; and third semiconductor chips stacked on the second semiconductor chip in a second direction perpendicular to the surface of the interposer substrate; in which the second semiconductor chip and the third semiconductor chips each include through vias, in which the interposer substrate comprises: a first redistribution layer; a second redistribution layer on the first redistribution layer; and a connection layer between the first redistribution layer and the second redistribution layer, in which the connection layer includes: a connection die; a conductive pillar spaced apart from the connection die in the first direction; and a mold layer covering a surface of the connection die and a surface of the conductive pillar, in which the second redistribution layer includes: a first bonding pad connected to the first semiconductor chip; a second bonding pad connected to the second semiconductor chip; an alignment mark located at a same level as the first bonding pad and the second bonding pad in the second direction; a first metal block overlapping the alignment mark in the second direction; and a second metal block overlapping the alignment mark in the second direction with the first metal block between the second metal block and the alignment mark, in which the alignment mark includes: a via; and a plate on the via, in which a surface of the via is in contact with a surface of the first metal block, in which the first metal block is spaced apart from the second metal block, and in which a height of the via is equal to or greater than a distance between a surface of the second metal block and a surface of the first metal block, in which the plate has first surfaces facing in the first direction, in which the first metal block has second surfaces opposite each other, in which the second metal block has third surfaces opposite each other, and in which the second surfaces and the third surfaces are located outside of the first surfaces.

A method of manufacturing a semiconductor package according to one or more embodiments may comprises forming an interposer substrate, wherein forming the interposer substrate may comprise forming a first metal block, forming a first insulating layer on the first metal block, forming a second metal block on the first insulating layer, forming a second insulating layer on the second metal block, and forming an alignment mark on the second insulating layer, wherein an entirety of the alignment mark may overlap the first metal block and the second metal block in a vertical direction, and a horizontal width of the first metal block and a horizontal width of the second metal block may be greater than a horizontal width of the alignment mark.

According to one or more embodiments, forming the interposer substrate may further comprise forming a first redistribution pattern at a same level as the second metal block, and forming a bonding pad at a same level as the alignment mark.

According to one or more embodiments, the method may further comprise forming third redistribution patterns, wherein the first metal block may be disposed on the third redistribution patterns, and wherein a horizontal width of the first metal block and a horizontal width of a second metal block may be greater than a horizontal width of each line of the third redistribution patterns.

According to one or more embodiments, a side surface of the first metal block and a side surface of the second metal block may be aligned in the vertical direction.

According to one or more embodiments, a planar area of the first metal block and a planar area the second metal block may be greater than a planar area of the alignment mark.

### BRIEF DESCRIPTION OF DRAWINGS

Example embodiments will be more clearly understood from the following brief description taken in conjunction with the accompanying drawings. The accompanying drawings represent non-limiting, example embodiments as described herein.

FIG. 1 is a top view of a semiconductor package according to one or more embodiments of the present disclosure.

FIG. 2 is a cross-sectional view according to I-I′ of FIG. 1.

FIG. 3 is an enlarged view of ‘EV1’ of FIG. 1.

FIG. 4 is a cross-sectional view taken along line A-A′ in FIG. 3.

FIG. 5 is a cross-sectional view of B-B′ of FIG. 3.

FIG. 6 is an enlarged view corresponding to ‘EV1’ in FIG. 1.

FIG. 7 is an enlarged view of an interposer substrate according to a comparative example.

FIG. 8 is a cross-sectional view of a semiconductor package according to one or more embodiments of the present disclosure.

FIG. 9 is a cross-sectional view of a semiconductor package according to one or more embodiments of the present disclosure.

FIGS. 10, 11, 12, and 13 are cross-sectional views of a method of manufacturing a semiconductor package according to one or more embodiments of the present disclosure.

### DETAILED DESCRIPTION

Hereinafter, a semiconductor package according to the present disclosure will be described with reference to the drawings.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

The specification uses the terms of degree including “substantially” or “about.” In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X.

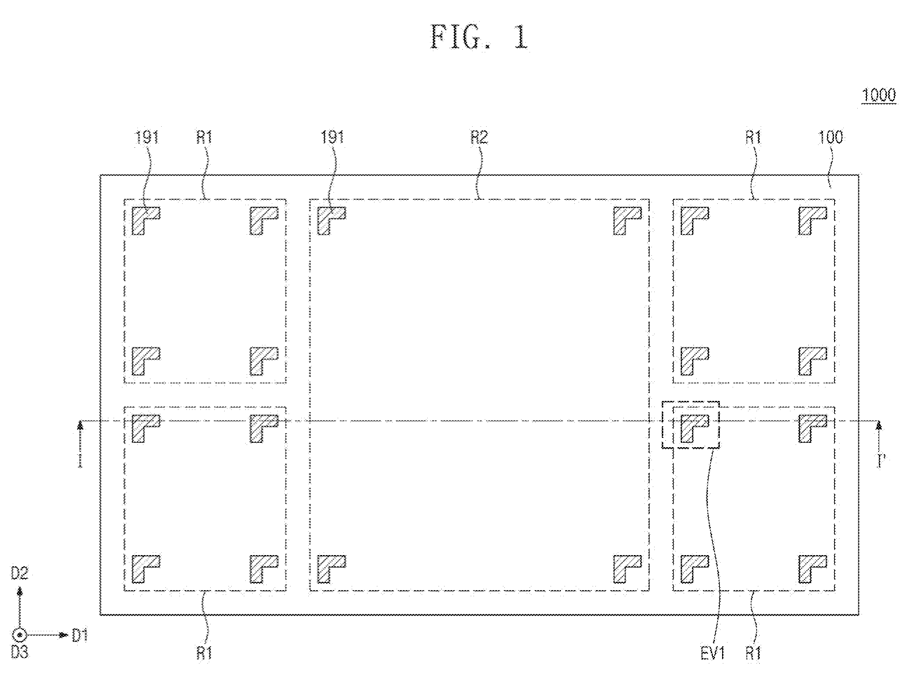

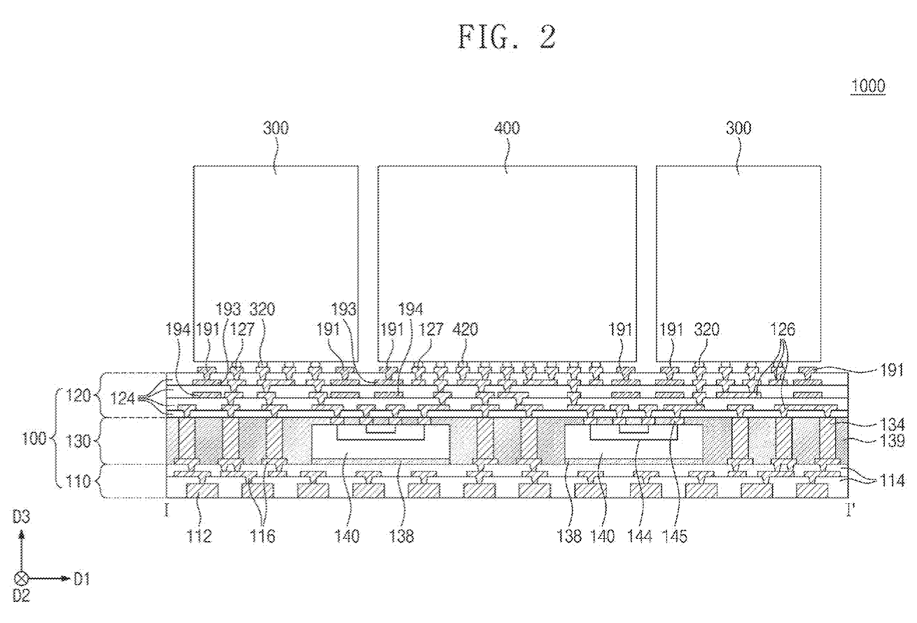

FIG. 1 is a plan view of a semiconductor package. FIG. 2 is a cross-sectional view of I-I′ of FIG. 1. To more clearly illustrate the configuration, some components of FIG. 2 are omitted from FIG. 1.

Referring to FIGS. 1 and 2, a semiconductor package 1000 may include an interposer substrate 100 and semiconductor chips 300, 400 disposed on the interposer substrate 100. The interposer substrate 100 may include chip mounting regions R1, R2 in which the semiconductor chips 300, 400 are respectively disposed on a top surface thereof. For example, the semiconductor chips 300, 400 may include a first semiconductor chip 300 and a second semiconductor chip 400. For example, the chip mounting regions R1, R2 may include a first chip mounting region R1 and a second chip mounting region R2. The first semiconductor chip 300 may be mounted in the first chip mounting region R1, and the second semiconductor chip 400 may be mounted in the second chip mounting region R2. The first semiconductor chip 300 may be electrically connected to the interposer substrate 100 through a first connection terminal 320. The second semiconductor chip 400 may be electrically connected to the interposer substrate 100 through a second connection terminal 420. The first connection terminal 320 and the second connection terminal 420 may be, for example, bumps or solder balls. Although FIG. 1 illustrates that region R2 is bigger than the regions R1, the embodiments are not limited to this configuration. For example, the region R2 may be the same size as the region R1.

Instead of the first semiconductor chip 300 and/or the second semiconductor chip 400, a packaged semiconductor chip may be mounted. The first chip mounting region R1 and the second chip mounting region R2 may be spaced apart from each other in the first direction D1 parallel to the top surface of the interposer substrate 100. A plurality of the first chip mounting regions R1 may be parallel to the top surface of the interposer substrate 100 and may be adjacent to each other in a second direction D2 intersecting the first direction D1. It is described that the first chip mounting region R1 and the second chip mounting region R2 are provided, but the chip mounting regions may be variously changed according to the package design.

One or more alignment marks 191 may be disposed on each of the first chip mounting region R1 and the second chip mounting region R2. The optical equipment may detect the alignment marks 191 to determine the mounting positions of the semiconductor chips 300 and 400 on the interposer substrate 100. For example, the alignment marks 191 may be arranged in a 2×2 matrix on each of the first chip mounting region R1 and the second chip mounting region R2. For example, each of the first chip mounting region R1 and the second chip mounting region R2 may have a rectangular shape. For example, a plurality of the alignment marks 191 may be disposed on vertex portions of the first chip mounting region R1 and may be disposed on vertex portions of the second chip mounting region R2. The alignment mark 191 may overlap the first semiconductor chip 300 in a third direction D3 perpendicular to the top surface of the interposer substrate 100. The alignment mark 191 may overlap the second semiconductor chip 400 in the third direction D3. A connection terminal such as a solder ball and a bump may not be disposed on the alignment mark 191. Although FIG. 1 shows the alignment marks arranged in a 2x2 matrix, the embodiments are not limited to this configuration. For example, each region may contain a fewer number of alignment marks, or a higher number of alignment marks. In one or more examples, an alignment mark may be placed in one corner of a region. In one or more examples, an alignment mark may be placed in each corner of a region and at a middle point on an edge of the region between each corner.

The interposer substrate 100 may include a first redistribution layer 110, a connection layer 130, and a second redistribution layer 120. The first redistribution layer 110 may be referred to herein as a lower redistribution layer. The second redistribution layer 120 may be referred to herein as an upper redistribution layer. The second redistribution layer 120 may be spaced apart from the first redistribution layer 110 in the third direction D3 with the connection layer 130 in between the first redistribution layer 110 and the second redistribution layer 120.

The first redistribution layer 110 may include an under-bump pattern 112, a first redistribution pattern 116, and first polymer insulating layers 114. The under-bump pattern 112 and the first redistribution pattern 116 may be interposed in the first polymer insulating layers 114. The first polymer insulating layers 114 are formed sequentially, but may be structurally observed as a single first polymer insulating layer. The under-bump pattern 112 and the first redistribution pattern 116 may comprise metal. A connection terminal such as a bump or a solder ball may be disposed on a bottom surface of the under-bump pattern 112. The first polymer insulating layers 114 may be formed from a photosensitive insulating dielectric (PID). The first polymer insulating layers 114 may include, for example, polyimide.

The connection layer 130 may include a connection die 140, a vertical conductive pillar 134, and a mold layer 139. The connection die 140 may be referred to herein as a bridge or a silicon bridge. The connection die 140 may overlap, in the third direction, with a part of the first semiconductor chip 300 and a part of the second semiconductor chip 400 adjacent to each other in the first direction D1. The connection die 140 may include a semiconductor substrate, a connection wiring 144, and a connection pad 145. The semiconductor substrate may be, for example, a silicon substrate. The connection wiring 144 may be interposed in an insulating layer disposed on the semiconductor substrate. The connection wiring 144 may extend in the first direction D1 and/or the second direction D2. The insulating layer may include, for example, an insulating material such as silicon oxide, silicon nitride, polyimide, and benzocyclobutene. The connection pad 145 may be electrically connected to the connection wiring 144 and may be exposed from the insulating layer. A top surface of the connection die 140 may be an active surface, and a bottom surface of the connection die 140 may be an inactive surface. An adhesive layer 138 may be disposed between the bottom surface of the connection die 140 and the top surface of the first redistribution layer 110. The adhesive layer 138 may comprise a polymeric material and, for example, may be formed from a die attach film. The vertical conductive pillar 134 may be spaced apart from the connection die 140 in the first direction D1 and/or the second direction D2. The vertical conductive pillar 134 may be a metal pillar extending in the third direction D3. The vertical conductive pillar 134 may be, for example, a copper pillar. The mold layer 139 may cover a side surface of the connection die 140 and a side surface of the vertical conductive pillar 134. A top surface of the connection pad 145 and a top surface of the vertical conductive pillar 134 may be exposed from the mold layer 139. The mold layer 139 may be formed, for example, from an epoxy molding compound.

The second redistribution layer 120 may include a second redistribution pattern 126, second polymer insulating layers 124, a first metal block 193, a second metal block 194, a bonding pad 127, and the alignment mark 191. The second polymer insulating layers 124 are formed sequentially. However, in one or more examples, these layers may be structurally observed as a single second polymer insulating layer 124. The second polymer insulating layers 124 may be formed from a photosensitive insulating material (e.g., Photo-Imageable Dielectric, PID). The second polymer insulating layers 124 may include, for example, polyimide. The second redistribution pattern 126, the first metal block 193, and the second metal block 194 may be disposed in the second polymer insulating layers 124. A top surface of the bonding pad 127 and the alignment mark 191 may be exposed from the second polymer insulating layers 124. The second redistribution pattern 126, the first metal block 193, the second metal block 194, the bonding pad 127, and the alignment marks 191 may include a metal. That is, the semiconductor package 1000 according to the present disclosure may be a 2.3D package. The semiconductor package 1000 may include a redistribution layer interposer in which a silicon bridge is embedded.

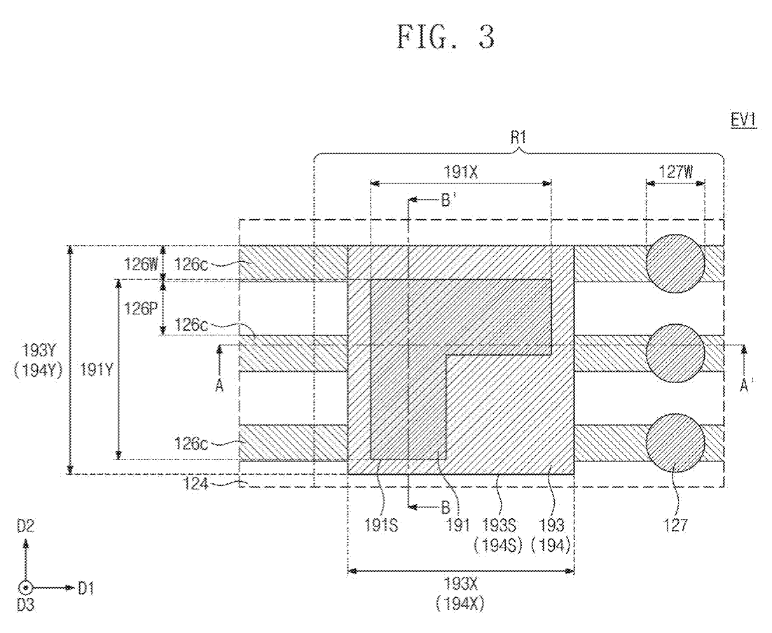

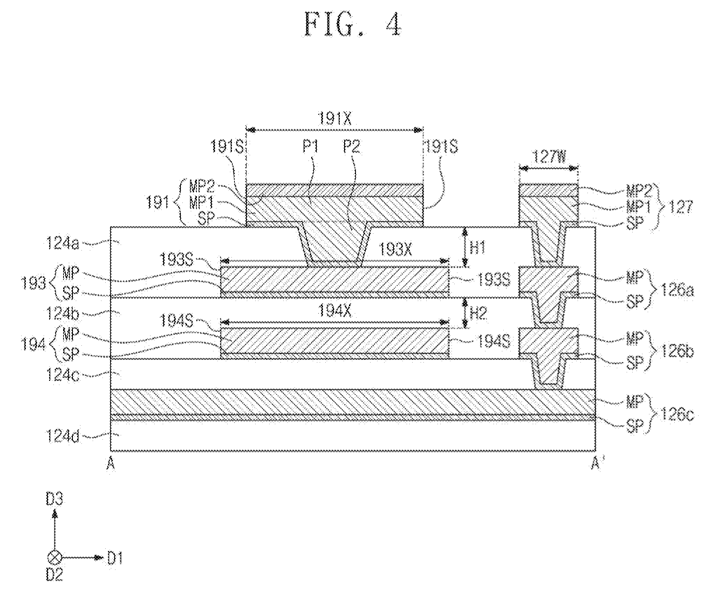

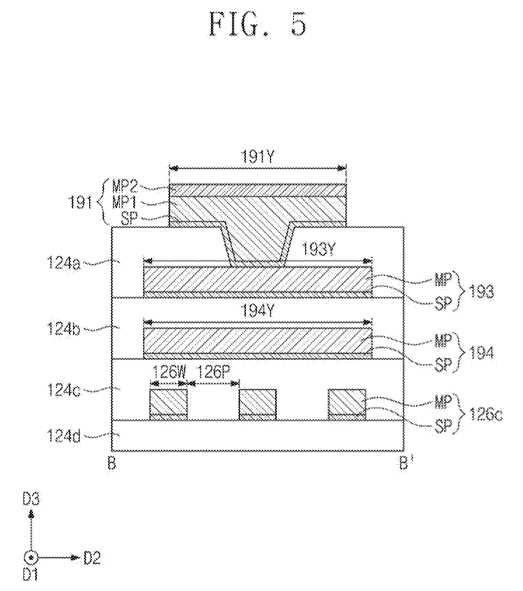

FIG. 3 is an enlarged view of ‘EV1’ of FIG. 1. FIG. 4 is a cross-sectional view taken along line A-A′ in FIG. 3. FIG. 5 is a cross-sectional view of B-B′ of FIG. 3.

Referring to FIGS. 2, 3, 4, and 5, the alignment mark 191 may be positioned at the same level as the bonding pad 127 in the third direction D3. A first metal block 193 may be disposed below the alignment mark 191. A second redistribution pattern 126a may be disposed below the bonding pad 127. The second redistribution pattern 126a may be defined as an N layer. In one or more examples, the N layer may refer to an Nth layer in the third direction D3 from the lower surface of the second redistribution layer 120 among the second redistribution patterns 126 that are stacked in the third direction D3. In one or more examples, the second redistribution pattern 126a of the N layer refer to an uppermost second redistribution pattern 126a among the stacked second redistribution patterns 126.

The first metal block 193 and the second redistribution pattern 126a of the N layer may be located at the same level in the third direction D3. The second polymer insulating layer 124a of an N+1 layer may be disposed between the alignment mark 191 and the first metal block 193 and between the bonding pad 127 and the second redistribution pattern 126a adjacent in the third direction D3. In this specification, the N+1 layer means an (N+1)th layer in the third direction D3 from the lower surface of the second redistribution layer 120 among the second polymer insulating layers 124 that are stacked in the third direction D3. In one or more examples, the second polymer insulating layer 124a of the N+1 layer means the uppermost second polymer insulating layer 124a among the stacked second polymer insulating layers 124.

The alignment mark 191 may include a plate P1 and a via P2. The plate P1 may be spaced apart from the top surface of the first metal block 193, and the bottom surface of the via P2 may be in contact with the top surface of first metal block 193. The bonding pad 127 may also include a via, which may be in contact with the top surface of the second redistribution pattern 126a. A second metal block 194 may be disposed below the first metal block 193. A second redistribution pattern 126b of an N−1 layer may be disposed at the same level in the third direction D3 as the second metal block 194. The second polymer insulating layer 124b of the N layer may be disposed between the first metal block 193 and the second metal block 194 and between the second redistribution pattern 126a and the second redistribution pattern 126b adjacent in the third direction D3. The second metal block 194 may be spaced apart from the first metal block 193 with the second polymer insulating layer 124b of the N layer interposed therebetween. A second redistribution pattern 126c of an N-2 layer may be disposed below the second metal block 194. A second polymer insulating layer 124c of the N-1 layer may be disposed between the second metal block 194 and the second redistribution pattern 126c of the N-2 layer adjacent in the third direction D3 and between the second redistribution patterns 126b and 126c of the N−1 layer and the N−2 layer adjacent in the 3rd direction D3. The second polymer insulating layer 124d of the N-2 layer may be disposed under the second redistribution pattern 126c of the N-2 layer. N may be greater than 3, for example 5.

A first separation distance H1 between the bottom surface of the plate P1 of the alignment mark 191 and the top surface of the first metal block 193, and a second separation distance H2 between the bottom surface the first metal block 193 and the top surface the second metal block 194 may be 2 μm to 5 μm. The first separation distance H1 may be greater than the second separation distance H2. For example, the first separation distance H1 may be 4 μm and the second separation distance H2 may be 3 μm. The first separation distance H1 may correspond to a thickness of the second polymer insulating layer 124a of the N+1 layer, and the second separation distance H2 may correspond to a thickness of the second polymer insulation layer 124b of the N layer. In one or more examples, the first separation distance H1 may be equal to the second separation distance H2. In one or more examples, the second separation distance H2 may be greater than the first separation distance H1.

In a plan view, the alignment mark 191 may have an “L” shape. The alignment mark 191 may have a first width 191X in the first direction D1. The first metal block 193 may have a second width 193X in the first direction D1. The second metal block 194 may have a third width 194X in the first direction D1. The second width 193X and the third width 194X may be greater than the first width 191X. For example, the second width 193X and the third width 194X may be at least 1.2 times greater than the first width 191X. The second width 193X and the third width 194X may be, for example, 110 μm to 150 μm. The second width 193X and the third width 194X may be substantially the same.

The alignment mark 191 may have a fourth width 191Y in the second direction D2. The first metal block 193 may have a fifth width 193Y in the second direction D2. The second metal block 194 may have a sixth width 194Y in the second direction D2. The fifth width 193Y and the sixth width 194Y may be greater than the fourth width 191Y. The fifth width 193Y and the sixth width 194Y may be at least 1.2 times greater than the fourth width 191Y. The fifth width 193Y and the sixth width 194Y may be, for example, 110 μm to 150 μm. The fifth width 193Y and the sixth width 194Y may be substantially the same.

The alignment mark 191 may have a first planar area, the first metal block 193 may have a second planar area, and the second metal block 194 may have a third planar area. The second planar area and the third planar area may be substantially the same. The second planar area and the third planar area may be larger than the first planar area. The alignment mark 191 may be disposed in the first metal block 193 and in the second metal block 194 in a plan view. In a plan view, a first side surface 191S of the alignment mark 191 may be spaced apart from a second side surface 193S of the first metal block 193 and the third side surface 194S of the second metal block 194. In a plan view, the second side surface 193S and the third side surface 194S may surround the first side surface 191S. In a cross-sectional view, the plate P1 of the alignment mark 191 may have a pair of first side surfaces 191S opposite each other, the first metal block 193 may have a pair of second side surfaces 193S opposite each other, and the second metal block 194 may have a pair of third side surfaces 194S opposite each other. The second side surfaces 193S and the third side surfaces 194S may be located from outside the first side surfaces 191S. The first side surface 191S may not be aligned with the second side surface 193S and the third side surface 194S in the third direction D3. The second side surface 193S and the third side surface 194S may be aligned in the third direction D3. As understood by one of ordinary skill in the art, the embodiments are not limited to an “L” shape. For example, the alignment mark may be any suitable shape such as a square, rectangle, triangle, etc.

The bonding pad 127 may have a shape of a circle from a plan view. The bonding pad 127 may have a first diameter 127W. The first width 191X and the fourth width 191Y may be two to three times larger than the first diameter 127W. The alignment mark 191 may have a shape different from that of the bonding pad 127 in a plan view.

The second redistribution pattern 126 may have a line width 126W. The second redistribution patterns 126 may be spaced apart according to a space width 126P therebetween. Each of the line width 126W and the space width 126P may be, for example, between 2 μm and 5 μm. The line width 126W and the space width 126P may be the same or different. Each of the line width 126W and the space width 126P may be smaller than the first width 191X and the fourth width 191Y, respectively.

Each of the first redistribution pattern 116, the second redistribution pattern 126, the first metal block 193, and the second metal block 194 may include a seed pattern SP and a metal pattern MP. The metal pattern MP may be disposed on the seed pattern SP. Each of the alignment mark 191 and the bonding pad 127 may include a seed pattern SP, a first metal pattern MP1, and a second metal pattern MP2. The first metal pattern MP1 may be disposed on the seed pattern SP, and the second metal pattern MP2 may be disposed on the first metal pattern MP1. The second metal pattern MP2 may include a metal material different from the first metal pattern MP1. The seed pattern SP may include, for example, at least one of titanium, tungsten, copper, or nickel. The metal pattern MP and the first metal pattern MP1 may include, for example, copper. The second metal pattern MP2 may include gold, for example.

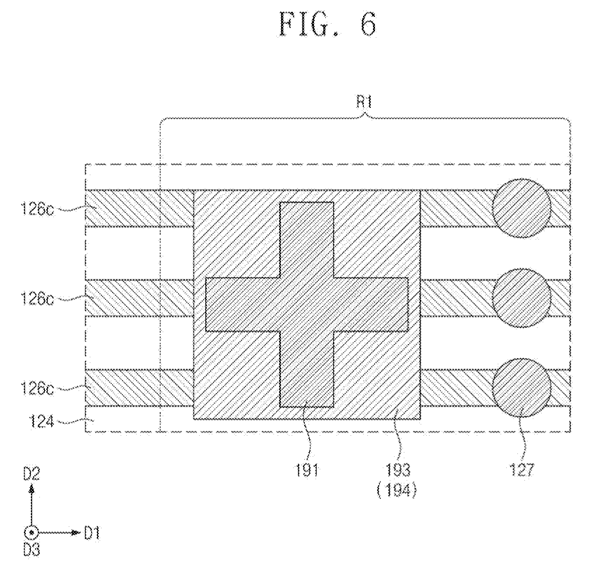

Referring to FIG. 6, according to one or more embodiments, the alignment mark 191 may have a cross shape, in a plan view. The alignment mark 191 may have various shapes as described above, and may have a larger planar area and a different shape than the top surface of the bonding pad 127.

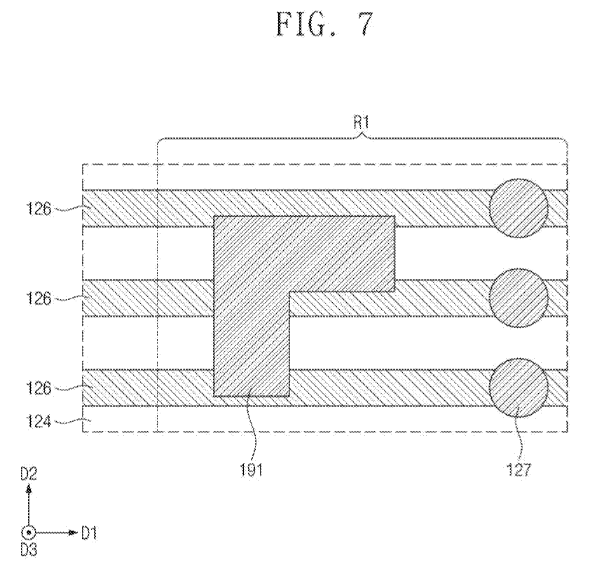

FIG. 7 is an enlarged view of an interposer substrate according to a comparative example. FIG. 7 is an enlarged view corresponding to EV1 in FIG. 1.

Referring to FIG. 7, the interposer substrate 100 according to the comparative example may not include the first metal block 193 and the second metal block 194. A second redistribution pattern 126 of a N-2 layer extending in the first direction D1 or the second direction D2 may be disposed below the alignment mark 191. Although illustrated as the second redistribution pattern 126 of the N-2 layer, the second redistribution pattern 126 may include to the N-1 layer, the N layer, or a layer below the N-2 layer. In one or more examples, the second redistribution pattern 126 below the alignment mark 191 may be observed through the alignment mark during inspection by the optical equipment. In one or more examples, the optical equipment may not recognize the alignment mark 191. Therefore, in this situation, the operator has to manually proceed with alignment, which is inefficient. According to the present disclosure, the first metal block 193 and the second metal block 194 may be disposed below the alignment mark 191, thereby preventing the underlying second redistribution pattern 126 from being visible. The entire alignment mark 191 may overlap the first metal block 193 and the second metal block 194 in the third direction D3, whereby visibility of the alignment mark 191 may be improved. When the first metal block 193 and the second metal block 194 are stacked together, the possibility of the second redistribution pattern 126 being visible may be reduced compared to the case where only the first metal block 193 is used. The first metal block 193 and the second metal block 194 have the same horizontal width, and their side surfaces may be aligned in the third direction D3, thereby preventing the occurrence of visible patterns or contrast differences that may arise when misalignment occurs.

In one or more examples, the interposer substrate 100 may be provided with the first metal block 193 and the second metal block 194 to increase an amount of metal. The semiconductor chips 300 and 400 disposed on the interposer substrate 100 are made of a silicon material and have a low equivalent thermal expansion coefficient (Equivalent CTE), and the interposer substrate 100 may have a relatively high thermal expansion coefficient based on an organic material. By increasing the amount of the metal having a low coefficient of thermal expansion relative to an amount of the second polymer insulating layer 124 having a high coefficient of thermal expansion (CTE) in the second redistribution layer 120, the overall coefficient of thermal expansion of the interposer substrate 100 decreases, and thus, the warpage may be reduced by reducing the difference from the equivalent coefficient of thermal expansion. As a result of the warpage reduction, delamination of internal layers of the interposer substrate 100 or debonding from externally mounted components (e.g., semiconductor chips) may be reduced.

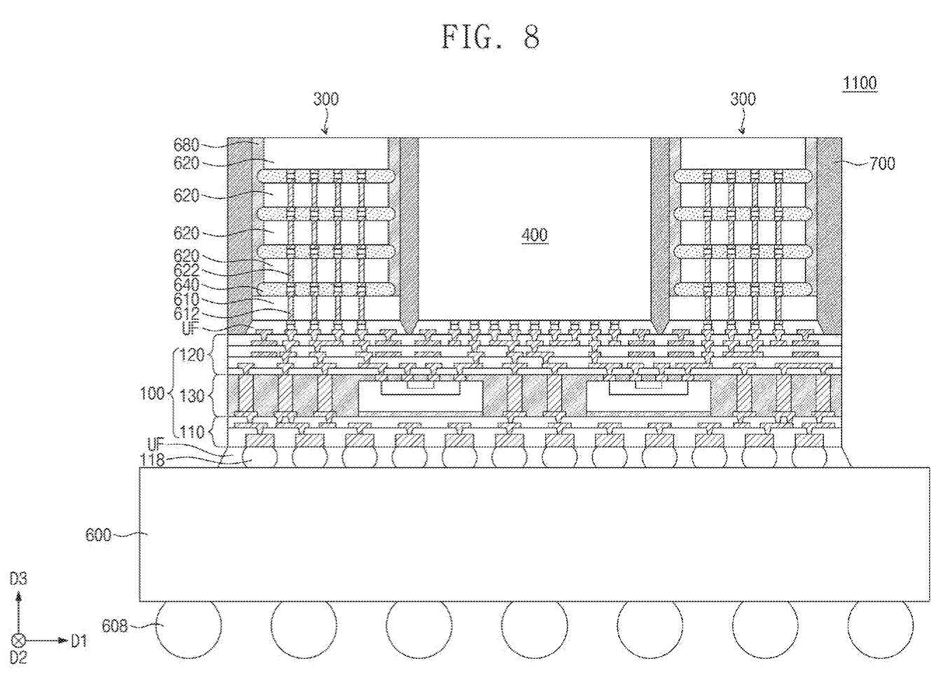

FIG. 8 is a semiconductor package according to one or more embodiments.

Referring to FIG. 8, the semiconductor package 1100 may further include a package substrate 600. The package substrate 600 may be, for example, a printed circuit board. The package substrate may include a substrate base, metal wirings in the substrate base, a top pad on a top surface of the substrate base and a bottom pad on a bottom surface of the substrate base. The substrate base may be composed of a single base layer or a structure in which a plurality of base layers are stacked. The substrate base may be made of at least one of, for example, a phenolic resin, an epoxy resin, or a polyimide. The substrate base may include at least one of, for example, FR4 (Frame Retardant 4), tetrafunctional epoxy, polyphenylene ether, epoxy/polyphenylene oxide, BT (Bismaleimide triazine), Thermount^{®} (Thermount® is a registered trademark of the DuPont Company), cyanate ester, polyimide, or liquid crystal polymer. The metal wirings may connect the top pad and the bottom pad. The top pad and the bottom pad may be exposed by a solder resist layer covering the top surface and bottom surface of the substrate base, respectively. An external connection terminal 608 may be disposed on the bottom surface pad of the package substrate 600. The external connection terminal 608 may be, for example, a solder ball or a bump. The external connection terminal 608 may electrically connect the semiconductor package 1100 to an external device.

The interposer substrate 100 may be disposed on the package substrate 600. The interposer substrate 100 may be mounted on the package substrate 600 by internal connection terminals 118. The internal connection terminals 118 may be, for example, a solder ball or a bump.

An underfill UF may be disposed between a bottom surface of the interposer substrate 100 and a top surface of the package substrate 600. The underfill UF may cover side surfaces of the internal connection terminals 118 and fill between the internal connection terminals 118.

The first semiconductor chip 300 may include a plurality of packaged semiconductor chips. The first semiconductor chip 300 may be a chip stack structure. The chip stack structure 300 may include a third semiconductor chip 610 and fourth semiconductor chips 620 stacked in the third direction D3 on the third semiconductor chip 610. The third semiconductor chip 610 may also be referred to as a logic die, a logic chip, a base die, a buffer chip, or a buffer die. The third semiconductor chip 610 may include a serial-parallel conversion circuit, a test logic circuit such as a design for test (DFT), a joint test action group (JTAG), a memory built-in self-test (MBIST), or a signal interface circuit such as a PHY. A horizontal area of the third semiconductor chip 610 may be greater than a horizontal area of the fourth semiconductor chips 620 in example embodiments. The third semiconductor chip 610 may include first through vias 612.

Each of the fourth semiconductor chips 620 may be a memory chip. The fourth semiconductor chips 620 may be, for example, any one of DRAM, SRAM, and NAND-FLASH. The fourth semiconductor chips 620 may be the same type of semiconductor chip having the same integrated circuit. The fourth semiconductor chips 620 may also be referred to as a core die or a core chip. Although FIG. 8 illustrates four of the fourth semiconductor chips 620 stacked, according to other embodiments, a multiple of four of the fourth semiconductor chips 620, for example, eight, twelve, or sixteen, may be stacked. The fourth semiconductor chips 620 may include second through vias 622.

The third semiconductor chip 610 and a lowermost fourth semiconductor chip 620 among the fourth semiconductor chips 620 may be connected to each other by using a connection terminal such as a micro bump. An adhesive layer 640 may be interposed between the third semiconductor chip 610 and the lowermost fourth semiconductor chip 620. The fourth semiconductor chips 620 adjacent to each other in the third direction D3 may be connected to each other using a connection terminal such as a micro bump. The adhesive layer 640 may be interposed between the fourth semiconductor chips 620 adjacent in the third direction D3. The adhesive layer 640 may be formed from, for example, a non-conductive film (NCF). In the exemplary embodiments, the micro-bumps may be used for connection between the third semiconductor chip 610 and the fourth semiconductor chips 620, as well as between the fourth semiconductor chips 620, as described. However, according to other embodiments, the semiconductor chips may be connected using hybrid metal bonding.

A second mold layer 680 may be disposed on the third semiconductor chip 610 and cover side surfaces of the fourth semiconductor chips 620. The second mold layer 680 may expose a top surface of a topmost fourth semiconductor chip 620 of the fourth semiconductor chips 620. The mold layer 139 of the interposer substrate 100 may be referred as a first mold layer 139. A third mold layer 700 may be disposed on a top surface of the interposer substrate 100. The third mold layer 700 may cover side surfaces of the chip stack structure 300 and side surfaces of the second semiconductor chip 400. The third mold layer 700 may fill between the side surfaces of the chip stack structure 300 and the side surfaces of the second semiconductor chip 400. The second mold layer 690 and the third mold layer 700 may be formed from an epoxy molding compound.

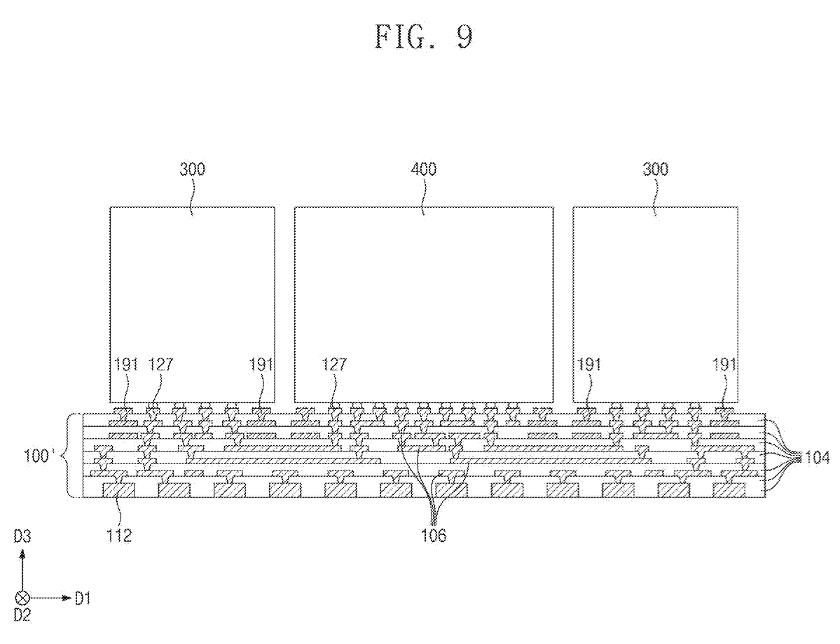

FIG. 9 is a cross-sectional view of a semiconductor package according to one or more embodiments. Except for those described below, the elements are the same as those described with reference to FIGS. 1 and 2, and redundant descriptions will be omitted. The interposer substrate 100′ may be a redistribution interposer substrate. The interposer substrate 100′ may not include the connection layer 130. The interposer substrate 100′ may include a plurality of polymer insulating layers 104 and redistribution patterns 106 disposed in the plurality of polymer insulating layers 104. The first metal block 193 and the second metal block 194 may be disposed at an upper portion of the interposer substrate 100′.

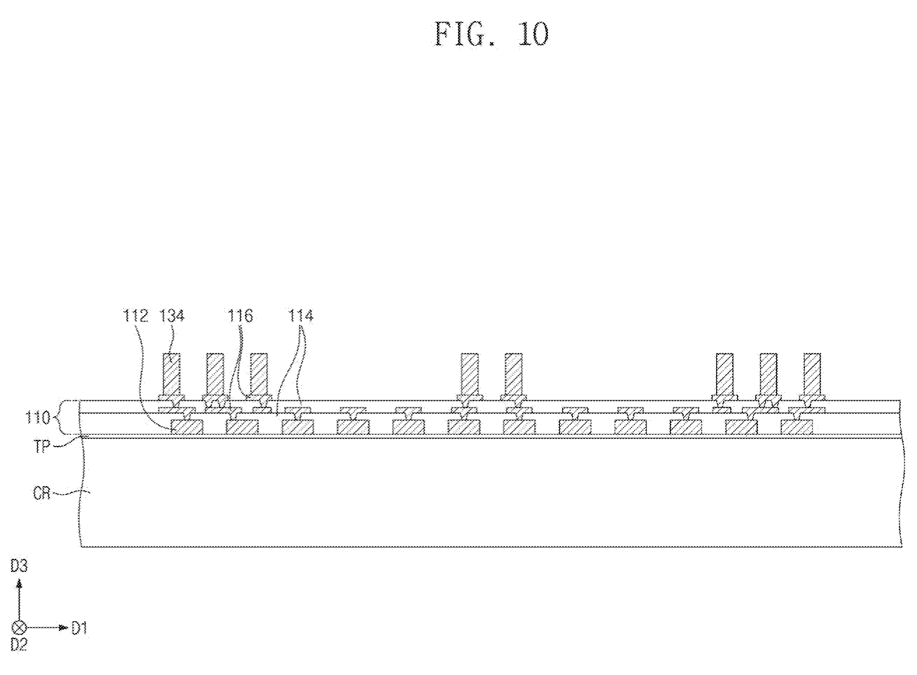

FIGS. 10, 11, 12, and 13 are cross-sectional views of a method of manufacturing a semiconductor package according to the present disclosure.

Referring to FIG. 10, a carrier substrate CR may be prepared. An adhesive tape TP may be provided on the carrier substrate CR. A metal foil may be provided on the adhesive tape TP. The metal foil may serve as a seed layer. The metal foil may be, for example, a copper foil. A first photomask pattern may be formed on the metal foil. The first photomask pattern may be formed through a process including forming, exposing, and developing a photoresist layer. The first photomask pattern may include a first opening defining a formation space of an under-bump pattern 112. The under-bump pattern 112 may be formed in the first opening of the first photomask. For example, the under-bump pattern 112 may be formed by performing an electroplating process using the metal foil as an electrode. The photo mask pattern may be removed. First polymer insulating layers 114 covering the under-bump pattern 112 may be formed. The first polymer insulating layers 114 may be formed by a coating process such as spin coating or slit coating. The first polymer insulating layers 114 may be patterned to have a second opening through which a via portion of the first redistribution pattern 116 is to be formed, by exposure, development, and curing processes. The second opening may expose a top surface of the under-bump pattern 112. Next, forming a seed layer on the first polymer insulating layers 114, forming a second photomask pattern including a third opening in which a line portion of the first redistribution pattern 116 is to be formed, electroplating the metal pattern MP in FIGS. 4 and 5 with the seed layer as an electrode, removing the second photomask patterns, and patterning the seed layer to form the seed pattern may proceed. As a result, the first redistribution pattern 116 including the seed pattern SP and the metal pattern MP in FIGS. 4 and 5 may be formed. The formation of the first polymer insulating layers 114 and the formation of the first redistribution pattern 116 may be repeated to form the first redistribution layer 110.

Forming the vertical conductive pillar 134 may include, prior to patterning the seed layer in the process of forming the topmost first redistribution pattern, forming a third photo mask pattern including a fourth opening defining a space in which the vertical conductive pillar is to be formed, electroplating the vertical conductive pillar 134 to fill the fourth opening with the seed layer with an electrode, and removing the third photo mask pattern.

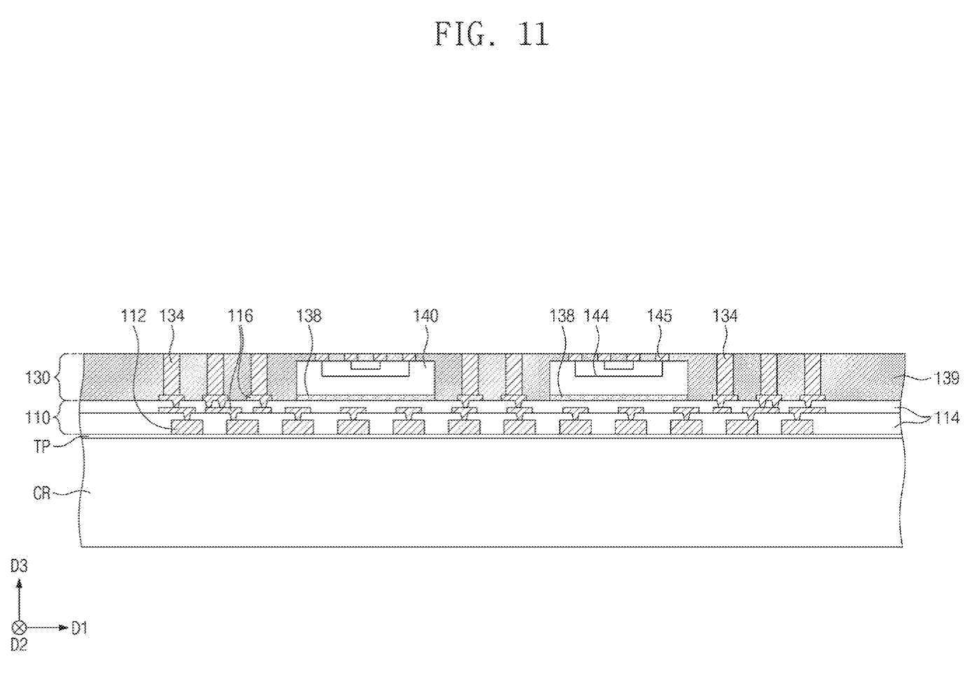

Referring to FIG. 11, a connection die 140 spaced apart from the vertical conductive pillar 134 in the first direction D1 and/or the second direction D2 may be disposed on the first redistribution layer 110. The connection die 140 may be attached with the top surface of the first redistribution layer 110 through an adhesive layer 138 disposed on the bottom surface thereof. The epoxy molding compound may then be used to form the first mold layer 139. Through the grinding process, a top surface of the vertical conductive pillar 134 and a top surface of a connection pad 145 of the connection die 140 may be exposed from the first mold layer 139. As a result, the connection layer 130 may be formed.

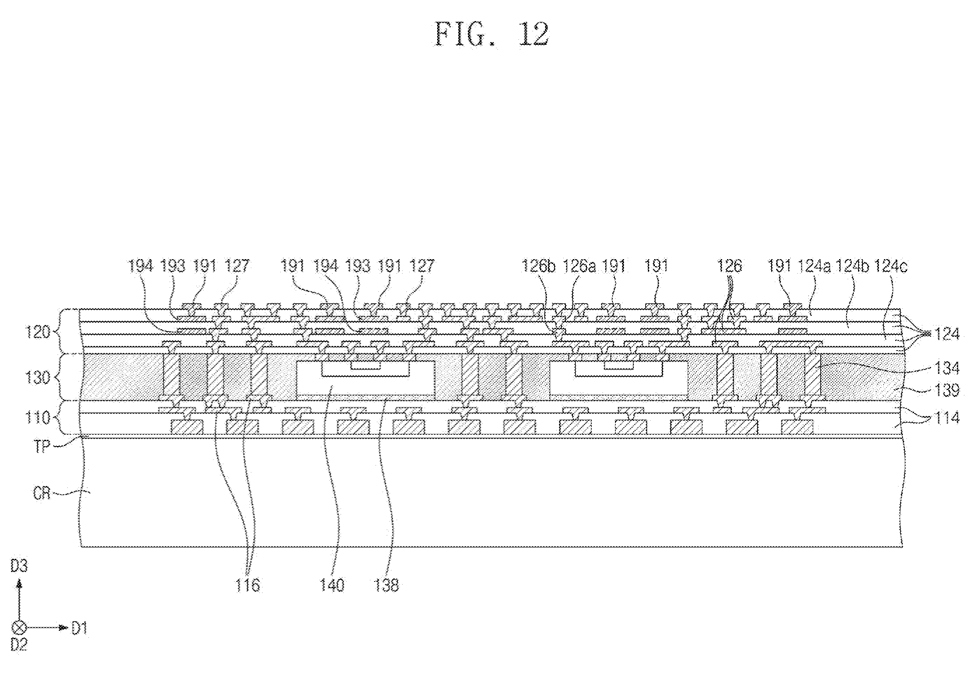

Referring to FIG. 12, the second polymer insulating layers 124 may be formed by substantially the same method the method of forming the first polymer insulating layers 114. The second redistribution pattern 126 may be formed through substantially the same method as the method of forming the first redistribution pattern 116. A second metal block 194 and a second redistribution pattern 126b may be formed together on the second polymer insulating layer 124c. The second metal block 194 may be formed using the same method as the method of forming the second redistribution pattern 126. After the second metal block 194 and the second redistribution pattern 126b are formed, the second polymer insulating layer 124b, which covers them, may be formed. The first metal block 193 and the second redistribution pattern 126a may be formed together on the second polymer insulating layer 124b. The first metal block 193 may be formed using the same method as the method of forming the second redistribution pattern 126. The second polymer insulating layer 124a covering the first metal block 193 and the second redistribution pattern 126a may be formed. An alignment mark 191 and a bonding pad 127 may be formed together on the second polymer insulating layer 124a. The bonding pad 127 may be formed on the uppermost second redistribution pattern 126a. An alignment mark 191 may be formed on the first metal block 193. The alignment mark 191 and the bonding pad 127 may be formed using an electroplating method as if the second redistribution pattern 126 had been formed previously.

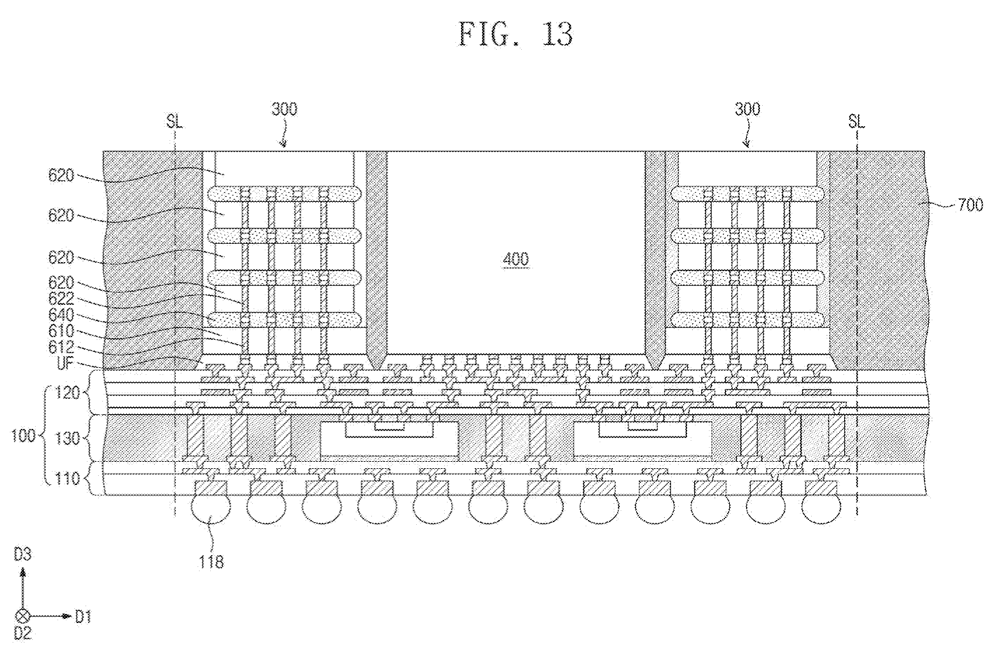

Referring to FIG. 13, it is possible to recognize the alignment mark 191 on the first chip mounting region R1 in FIG. 1 and to recognize the alignment mark 191 on the second chip mounting region R2 in FIG. 1 by using the optical equipment. The chip stack structure 300 may be mounted on the first chip mounting region R1. The second semiconductor chip 400 may be mounted on the second chip mounting region R2. An underfill UF may be formed by injecting an underfill material between the chip stack structure 300 and the second redistribution layer 120 and between the second semiconductor chip 400 and the second redistribution layer 120.

Next, the chip stack structure 300 and the third mold layer 700 covering the side surfaces and the top surface of the second semiconductor chip 400 may be formed. A grinding process may proceed on the top surface of the third mold layer 700 such that the top surface of second semiconductor chip 400 and the top surface of chip stack structure 300 are exposed. The carrier substrate CR, the adhesive tape TP and the metal foil may be removed. As the metal foil is removed, the under-bump patterns 112, which were electrically connected through the metal foil, may be electrically isolated. Internal connection terminals 118 may be formed on bottom surfaces of the under-bump patterns 112. Along a sawing line SL, the interposer substrate 100 and the third mold layer 700 may be cut. As a result, the semiconductor package 1000 of FIGS. 1 and 2 may be formed. The interposer substrate 100 may then be mounted on the package substrate 600 of FIG. 8. After the interposer substrate 100 is mounted, an underfill material may be injected between the bottom surface of the interposer substrate 100 and the top surface of the package substrate 600 to form an underfill UF. As a result, the semiconductor package 1100 of FIG. 8 may be formed.

According to one present disclosure, the interposer may comprise a first metal block and a second metal block that entirely overlap the alignment mark in the vertical direction. The first metal block and the second metal block may improve visibility of the alignment mark.

According to another present disclosure, the first metal block and the second metal block may reduce the overall coefficient of thermal expansion of the interposer, by increasing an amount of metal relative to that of the polymer insulating layer. As a result, the warpage of the semiconductor package may be reduced.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims.

What is claimed is:

1. A semiconductor package comprising:
an interposer substrate; and
a semiconductor chip on the interposer substrate,
wherein the interposer substrate comprises:
a bonding pad on a surface of the interposer substrate and connected to the semiconductor chip;
an alignment mark spaced apart from the bonding pad in a first direction parallel to the surface of the interposer substrate; and
a first metal block and a second metal block, each overlapping with an entire area of the alignment mark in a second direction perpendicular to the surface of the interposer substrate,
wherein the alignment mark has a first width in the first direction,
wherein the first metal block has a second width in the first direction,
wherein the second metal block has a third width in the first direction, and
wherein each of the second width and the third width is greater than the first width.

2. The semiconductor package of claim 1,
wherein the interposer substrate further comprises:
a first polymer insulating layer between the alignment mark and the first metal block; and
a second polymer insulating layer between the first metal block and the second metal block,
wherein each of the first polymer insulating layer and the second polymer insulating layer has a thickness between 2 μm to 5 μm.

3. The semiconductor package of claim 1,
wherein the alignment mark overlaps the semiconductor chip in the second direction.

4. The semiconductor package of claim 1,
wherein the alignment mark has a fourth width in a third direction that is parallel to the surface of the interposer substrate and perpendicular to the first direction,
wherein the first metal block has a fifth width in the third direction,
wherein the second metal block has a sixth width in the third direction, and
wherein each of the fifth width and the sixth width is greater than the fourth width.

5. The semiconductor package of claim 1,
wherein a shape of the alignment mark is different from a shape of the bonding pad.

6. The semiconductor package of claim 1,
wherein the second width is equal to the third width.

7. The semiconductor package of claim 1,
wherein the bonding pad has a first diameter in the first direction, and
wherein the first width is greater than the first diameter.

8. The semiconductor package of claim 1,
wherein the interposer substrate further comprises a first redistribution pattern extending in the first direction, and
wherein the first redistribution pattern is spaced apart from the alignment mark in the second direction with the first metal block and the second metal block between the first redistribution pattern and the alignment mark.

9. The semiconductor package of claim 1,
wherein the interposer substrate further comprises a second redistribution pattern and a third redistribution pattern,
wherein the second redistribution pattern is at a same level as the first metal block, and
wherein the third redistribution pattern is at a same level as the second metal block.

10. The semiconductor package of claim 1,
wherein the alignment mark comprises a via and a plate on the via,
wherein a surface of the via is in contact with a surface of the first metal block, and
wherein the plate is spaced apart from the first metal block.

11. The semiconductor package of claim 10,
wherein a first separation distance between a surface of the plate and a surface of the first metal block and a second separation distance between a surface of the first metal block and a top surface of the second metal block are each in a range of 2 μm to 5 μm.

12. The semiconductor package of claim 1,
wherein the alignment mark comprises:
a seed pattern;
a first metal pattern on the seed pattern; and
a second metal pattern on the first metal pattern,
wherein the second metal pattern comprises a different metal material from the first metal pattern.

13. The semiconductor package of claim 1,
wherein the second width and the third width are 1.2 times or more larger than the first width.

14. The semiconductor package of claim 1,
wherein the second width and the third width are between 110 μm and 150 μm.

15. A semiconductor package comprising:
an interposer substrate; and
a first semiconductor chip on the interposer substrate; and
a second semiconductor chip on the interposer substrate,
wherein the first semiconductor chip and the second semiconductor chip are spaced apart from each other in a first direction parallel to a surface of the interposer substrate, and
wherein the interposer substrate comprises:
an alignment mark on the surface of the interposer substrate; and
a first metal block overlapping the alignment mark in a second direction perpendicular to the surface of the interposer substrate,
wherein the alignment mark has a first area,
wherein the first metal block has a second area,
wherein the second area is greater than the first area, and
wherein the alignment mark is located within the first metal block.

16. The semiconductor package of claim 15,
wherein the alignment mark has a first surface,
wherein the first metal block has a second surface, and
wherein the second surface surrounds the first surface, and the first surface and the second surface are spaced apart from each other.

17. The semiconductor package of claim 15,
wherein the interposer substrate comprises:
a first redistribution layer;
a second redistribution layer on the first redistribution layer; and
a connection layer between the first redistribution layer and the second redistribution layer,
wherein the connection layer comprises:
a connection die;
a conductive pillar spaced apart from the connection die in the first direction; and
a mold layer on a surface of the connection die and a surface of the conductive pillar,
wherein the alignment mark is on the second redistribution layer,
wherein the first metal block is within the second redistribution layer, and
wherein the connection die overlaps the first semiconductor chip and the second semiconductor chip in the second direction.

18. The semiconductor package of claim 15,
wherein a second metal block is spaced apart from the alignment mark in the second direction with the first metal block interposed between the second metal block and the alignment mark,
wherein the second metal block has a third area,
wherein the third area is greater than the first area, and
wherein the alignment mark is located within the second metal block.

19. The semiconductor package of claim 18,
wherein the first metal block and the second metal block overlap each other.

20. A semiconductor package comprising:
a package substrate;
an interposer substrate on the package substrate;
a first semiconductor chip on the interposer substrate; and
a chip stack structure spaced apart from the first semiconductor chip in a first direction parallel to a surface of the interposer substrate,
wherein the chip stack structure comprises:
a second semiconductor chip; and
third semiconductor chips stacked on the second semiconductor chip in a second direction perpendicular to the surface of the interposer substrate;
wherein the second semiconductor chip and the third semiconductor chips each include through vias,
wherein the interposer substrate comprises:
a first redistribution layer;
a second redistribution layer on the first redistribution layer; and
a connection layer between the first redistribution layer and the second redistribution layer,
wherein the connection layer comprises:
a connection die;
a conductive pillar spaced apart from the connection die in the first direction; and
a mold layer covering a surface of the connection die and a surface of the conductive pillar,
wherein the second redistribution layer comprises:
a first bonding pad connected to the first semiconductor chip;
a second bonding pad connected to the second semiconductor chip;
an alignment mark located at a same level as the first bonding pad and the second bonding pad in the second direction;
a first metal block overlapping the alignment mark in the second direction; and
a second metal block overlapping the alignment mark in the second direction with the first metal block between the second metal block and the alignment mark,
wherein the alignment mark comprises:
a via; and
a plate on the via,
wherein a surface of the via is in contact with a surface of the first metal block,
wherein the first metal block is spaced apart from the second metal block, and
wherein a height of the via is equal to or greater than a distance between a surface of the second metal block and a surface of the first metal block,
wherein the plate has first surfaces facing in the first direction,
wherein the first metal block has second surfaces opposite each other,
wherein the second metal block has third surfaces opposite each other, and
wherein the second surfaces and the third surfaces are located outside of the first surfaces.
